(19) United States
(12) Patent Application Publication
(10) Pub. No.: US 2025/0258201 A1
(43) Pub. Date: Aug. 14, 2025

(54) APPARATUS FOR MEASURING A CURRENT IN A CONDUCTOR, METHOD FOR PRODUCING SUCH AN APPARATUS, AND METHOD FOR MEASURING A CURRENT IN A CONDUCTOR

(71) Applicant: Siemens Aktiengesellschaft, München (DE)

(72) Inventors: Roland Weiss, Erlangen (DE); Franz Meierhöfer, Kirchensittenbach (DE); Klaus Behringer, Igensdorf (DE); Daniel Pirstat, Amberg (DE)

(21) Appl. No.: 19/053,663

(22) Filed: Feb. 14, 2025

(30) Foreign Application Priority Data
Feb. 14, 2024 (DE) 10 2024 201 330.7

(51) Int. Cl. G01R 15/18; G01R 3/00; G01R 19/00

(52) U.S. Cl. CPC G01R 15/181; G01R 3/00; G01R 19/0092

(57) ABSTRACT

An apparatus for measuring a current in a conductor. The apparatus has at least one first and one second coil and the at least two coils have an identical coil body and have been wound with the same type of wire with the same number of winding layers and the same number of windings. The at least two coils are arranged electrically connected in series and spatially on top of one another. The at least two coils differ in the orientation of their windings such that the at least two coils form a supercoil. The conductor is passed through the supercoil in order to measure the current.

### CROSS-REFERENCE TO RELATED APPLICATION

This application claims the priority, under 35 U.S.C. § 119, of German Patent Application DE 10 2024 201 330.7, filed Feb. 14, 2024; the prior application is herewith incorporated by reference in its entirety.

### FIELD AND BACKGROUND OF THE INVENTION

The invention relates to an apparatus for measuring an electric current in a conductor, a method for producing a supercoil for measuring a current in a conductor and a method for measuring an electric current in a conductor.

Coils are used to measure alternating currents. The induced voltage, which is caused by the time-varying magnetic field of the current to be measured, for example the current in a primary conductor, as well as by external time-varying magnetic fields such as external fields, is used as a sensory quantity. Rogowski coils are usually constructed as annular structures and arranged around the primary conductor in such a way that the magnetic field of the primary current penetrates all windings as vertically as possible. In this case, windings mean the surfaces that are spanned by the windings of the coil. The closed annular structure with a constant product of cross-sectional area and winding density minimizes the influence of external magnetic fields as far as possible. In general, both the cross-sectional area and the winding density along the Rogowski coil are constant.

The external magnetic fields may have any desired spatial orientation, in contrast to the magnetic field of the measuring current or primary current. An ideal Rogowski coil would be virtually insensitive to external fields due to its symmetry. In practice, real Rogowski coils exhibit a clear sensitivity to time-varying external magnetic fields. Depending on the winding pattern of the Rogowski coil, time-varying magnetic field components that are parallel to the axis of rotation of the Rogowski coil and do not originate from the primary current may result in a significant output signal of the Rogowski coil. This results in an erroneous current measurement.

In simple winding patterns, as are applied in the case of very small Rogowski coils due to the limitations of the manufacturing technology, time-varying external fields that are aligned parallel to the axis of the primary current show the greatest influence on the output signal of the Rogowski coil. However, very small Rogowski coils are required for the measurement of alternating currents with an RMS value of less than 100 A in low-voltage applications in order to meet the requirements for a compact design of the measuring devices.

In addition to inductive couplings, capacitive couplings caused by time-varying electrical fields also play an important role. In general, the conductive winding of the Rogowski coil with all conductive surfaces of the environment forms a more or less complex capacitive structure. Due to the relatively large distances between the winding of the Rogowski coil and the conductive surfaces, for example the surface of the primary conductor, the coupling capacitances usually have very low values. However, since the potential difference with respect to these surfaces is very large compared to the measuring voltage at the ends of the Rogowski coil, even normal operating conditions in low-voltage networks can lead to significant measurement errors when measuring the current using Rogowski coils.

Typically, the described problem was solved by certain winding patterns of the Rogowski coils. The corresponding winding patterns are associated with a certain amount of effort and a significantly increased degree of complexity of the manufacturing process during manufacture. However, for very small, multilayered Rogowski coils, it is currently technically impossible to implement the corresponding winding patterns with sufficient quality due to their increased complexity in manufacture. Accordingly, Rogowski coils with an outer diameter smaller than about 30 mm show greatly increased measurement errors in the presence of corresponding interference fields.

In general, alternating currents with an RMS value of less than 100 A can also be measured for low-voltage applications using a toroidal core transformer. In addition to some advantages over Rogowski coils, these also have some disadvantages, such as higher costs, higher weight and a larger design or a significantly larger volume, for example.

In the past, the problem with capacitive interference coupling has been solved by integrating shielding surfaces into the structure of the Rogowski coils. These shielding surfaces have been kept at the measuring potential of the coils and thus provide the necessary counter-charges on the surface for shielding the electrical field. Since good shielding must not affect the time-varying magnetic field in the Rogowski coil and at the same time the space requirement of the Rogowski coil should not be significantly increased, the use of capacitive shields in small Rogowski coils is subject to certain limitations.

### SUMMARY OF THE INVENTION

It is accordingly an object of the invention to provide a method and apparatus for measuring a current in a conductor, and a method for producing such an apparatus, which overcome the above-mentioned and other disadvantages of the heretofore-known devices and methods of this general type and which provides for an alternative apparatus and method for measuring a current that compensates for or improves the disadvantages of the prior art.

With the above and other objects in view there is provided, in accordance with the invention, an apparatus for measuring a current in a conductor, the apparatus comprising:
at least two coils, being a first coil and a second coil;
the at least two coils having an identical coil body, and having been wound with a same type of wire, with a same number of winding layers, and a same number of windings;
the at least two coils being electrically connected in series and being arranged spatially on top of one another, and the at least two coils differing in an orientation of their windings, with the at least two coils forming a supercoil; and
the supercoil being formed to pass the conductor therethrough for measuring the current in the conductor.

In other words, the apparatus for measuring an electric current in a conductor comprises at least one first and one second coil, wherein the at least two coils have an identical coil body and have been wound with the same type of wire with the same number of winding layers and the same number of windings, wherein the at least two coils are arranged electrically connected in series spatially on top of one another and differ in the orientation of their windings such that the at least two coils form a supercoil, wherein the conductor is passed through the supercoil in order to measure the current.

It is advantageous here that interference couplings can be reduced by the apparatus according to the invention and a current can be measured more accurately overall. It is also advantageous that the apparatus according to the invention has a small installation space and a small volume and can thus be used particularly advantageously in low-voltage applications.

In one configuration, the coils have inputs and outputs and these inputs and outputs are twisted by 180° with respect to one another.

In a further configuration of the apparatus according to the invention, the at least two coils are electrically connected to one another in their outer winding layers and the overall signal is determined between the inner winding layers.

In a further configuration, the connection of the outer winding layers is grounded.

With the above and other objects in view there is also provided, in accordance with the invention, a method for producing a supercoil for measuring a current in a conductor. The method comprises the following steps:
winding a first coil;
winding a second coil, wherein the two coils have an identical coil body and are wound with the same type of wire with the same number of winding layers and the same number of windings, wherein the two coils differ in the orientation of their windings;
assembling the first coil and the second coil to form a supercoil, wherein the two coils are arranged electrically connected in series spatially on top of one another.

In one configuration of the method, the first coil is wound right-handed counter-clockwise, and the second coil is wound right-handed clockwise, wherein, upon assembly, inputs and outputs are swapped in the second coil or the second coil is tilted by 180°.

In one configuration of the method, the first coil is wound right-handed counter-clockwise and the second coil is wound left-handed clockwise, wherein, upon assembly, inputs and outputs are swapped in the second coil and the second coil is tilted by 180°.

In one configuration of the method, the first coil is wound right-handed clockwise and the second coil is wound right-handed counter-clockwise, wherein, upon assembly, inputs and outputs are swapped in the second coil and the second coil is tilted by 180°.

In one configuration of the method, the first coil is wound right-handed clockwise and the second coil is wound left-handed counter-clockwise, wherein, upon assembly, inputs and outputs are swapped in the second coil and the second coil is tilted by 180°.

In one configuration of the method, the first coil is wound left-handed clockwise and the second coil is wound left-handed counter-clockwise, wherein, upon assembly, inputs and outputs are swapped in the second coil or the second coil is tilted by 180°.

In one configuration of the method, the first coil is wound left-handed clockwise and the second coil is wound right-handed counter-clockwise, wherein, upon assembly, inputs and outputs are swapped in the second coil and the second coil is tilted by 180°.

In one configuration of the method, the second coil is wound left-handed counter-clockwise and the second coil is wound left-handed clockwise, wherein, upon assembly, inputs and outputs are swapped in the second coil or the second coil is tilted by 180°.

In one configuration of the method, the first coil is wound left-handed counter-clockwise and the second coil is wound right-handed clockwise, wherein, upon assembly, inputs and outputs are swapped in the second coil and the second coil is tilted by 180°.

With the above and other objects in view there is also provided, in accordance with the invention, a method for measuring a current in a conductor. The method comprises the following steps:
providing a supercoil as described;
passing a conductor through the supercoil; and
measuring the current in the supercoil.

Other features which are considered as characteristic for the invention are set forth in the appended claims.

Although the invention is illustrated and described herein as embodied in an apparatus for measuring a current in a conductor, a method for producing such an apparatus, and a method for measuring a current in a conductor, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE FIGURES

FIG. 1A is a diagram showing a coil wound right-handed counter-clockwise;

FIG. 1B is a diagram showing a coil wound right-handed clockwise;

FIG. 1C is a diagram showing a coil wound left-handed counter-clockwise; and

FIG. 1D is a diagram showing a coil wound left-handed clockwise;

FIG. 2 shows a supercoil consisting of first coil and second coil and conductor;

FIG. 3 is an equivalent circuit diagram of a coil with four winding layers;

FIG. 4 is an illustration of a first coil and second coil with electrically connected outer winding layers;

FIG. 5 is an equivalent circuit diagram of the two coils according to FIG. 4;

FIG. 6 is an illustration of a first coil and second coil with electrically connected outer winding layers that are grounded; and

FIG. 7 is a flow diagram of a method for measuring a current in a conductor.

### DETAILED DESCRIPTION OF THE INVENTION

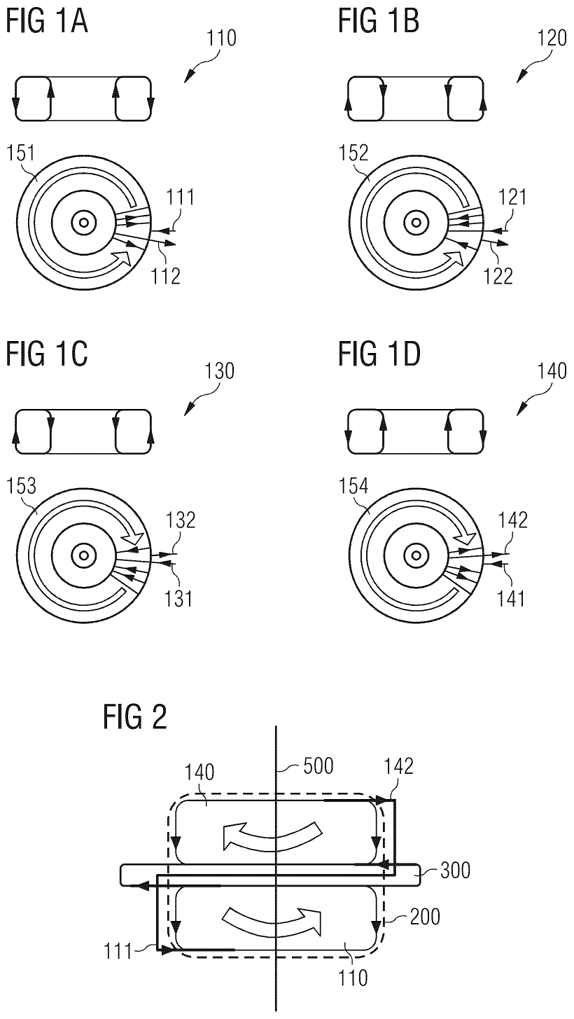

FIGS. 1A to 1D show coils 110; 120; 130; 140. In this case, the coil 110 from FIG. 1A is wound right-handed counter-clockwise. This means that, starting from an input 111, the wire is guided below the coil body 151, upward on the inside and then again above the coil body 151, until the output 112 is reached. The right-handed winding in the illustration of FIG. 1A shows that the windings move counter-clockwise. Looking laterally at the coil body 151 of the coil 110 so that the windings are wound toward the observer, it can be seen that the windings are oriented counter-clockwise. In the illustration of FIG. 1A, this view is the view from above onto the side of the coil 110.

FIG. 1B also shows a coil 120 comprising a coil body 152 and windings from an input 121 to an output 122. The winding is in turn right-handed, and so the windings move counter-clockwise on the coil body 152. Looking again as an observer at the coil laterally so that the windings move toward the observer, it can be seen in the profile of the coil body 152 that the windings are arranged clockwise around it.

FIGS. 1C and 1D show the coils 130 and 140, respectively; each of the coils 130, 140 is wound left-handed. In FIG. 1C, the winding is oriented left-handed counter-clockwise and, in FIG. 1D, the windings are oriented left-handed clockwise.

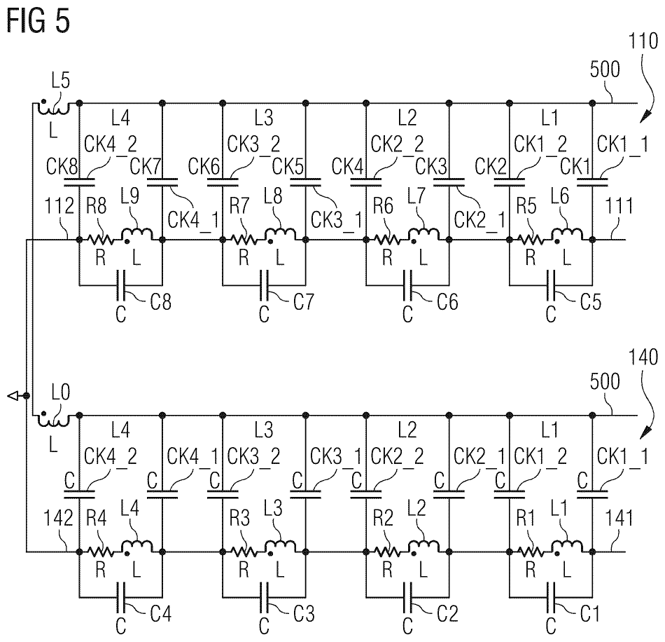

The coil 110 of FIG. 4A can be converted into the coil 130 of FIG. 1C either by swapping inputs and outputs 111, 112; 121, 122; 131, 132; 141, 142, or by tilting them by 180°. The same applies to the coil 120 of FIG. 1B and the coil 140 of FIG. 1D.

The problem of inductive and capacitive interference coupling is solved by using at least two Rogowski coils 110; 120; 130; 140. It should be noted that the at least two coils 110; 120; 130; 140 used should be designed to be largely identical. The at least two coils 110; 120; 130; 140 have an identical coil body 151; 152; 153; 154 and have been wound with the same type of wire with the same number of winding layers and the same number of windings.

To compensate for inductive interference, at least two coils 110; 120; 130; 140 are assembled to form a supercoil 200, as is illustrated in FIG. 2. In this case, the at least two coils 110; 140 are electrically connected in series and arranged on top of one another, wherein the two coils 110; 140 differ in the orientation of their windings. In order to measure the current in a conductor 500, said conductor must be passed through the supercoil 200. The output 142 of the coil 140 is connected to the input 111 of the coil 110, resulting in the series connection. The coil body 151; 152; 153; 154 is toroidal and the wire is guided, for example, through the torus and then around the outside and the exact opposite occurs at the corresponding coil partner, that is to say said coil is guided first around the outside and then back inside. The further windings are placed in the same direction around the coil body 151; 152; 153; 154. Subsequently, one of the coils is tilted by 180°, wherein, for example, a combination of right-handed clockwise according to FIG. 1B coil 120 and left-handed counter-clockwise according to FIG. 1C coil 130 is produced.

In the other case, the winding direction of the toroidal coil body 151; 152; 153; 154 is varied. The winding direction of the individual windings is retained in this case. The wire is passed through the inside of both and back out. However, the further windings are placed around the torus in different directions. For example, the combination right-handed counter-clockwise according to FIG. 1A coil 110 and left-handed clockwise according to FIG. 1D in the coil 140 is produced.

In Rogowski coils with one winding layer, the winding patterns right-handed counter-clockwise (FIG. 1A) and left-handed counter-clockwise (FIG. 1C) can be converted into one another by reversing the polarity or tilting by 180°. The same applies to the winding pattern pair right-handed clockwise (FIG. 1B) and left-handed clockwise (FIG. 1D). In the case of multiple winding layers, these winding pattern pairs differ in terms of external field sensitivity and capacitive coupling. These properties can be utilized to compensate for the respective interference couplings. A reversal of polarity refers to the interchanging of input and output.

According to FIG. 2, two Rogowski coils, whose windings have the same orientation, but whose coil bodies have been wound in different directions (for example first coil 110 right-handed counter-clockwise and second coil 140 left-handed clockwise) are mounted on top of one another, for example on the top and bottom of a printed circuit board. Both coils 110; 140 are twisted by 180° with respect to one another, as is illustrated in FIG. 2, so a good compensation of the interference couplings caused by inaccuracies in manufacture due to external magnetic fields results when both coils 110; 140 are connected in series.

By mounting the two coils 110; 140 on top of one another, the interference from magnetic fields that are oriented parallel to the current is reduced since a right-handed coil is combined with a left-handed coil. Twisting the connections (inputs and outputs 111, 112; 121, 122; 131, 132; 141, 142) by 180° reduces interference from magnetic fields perpendicular to the axis of the conductor.

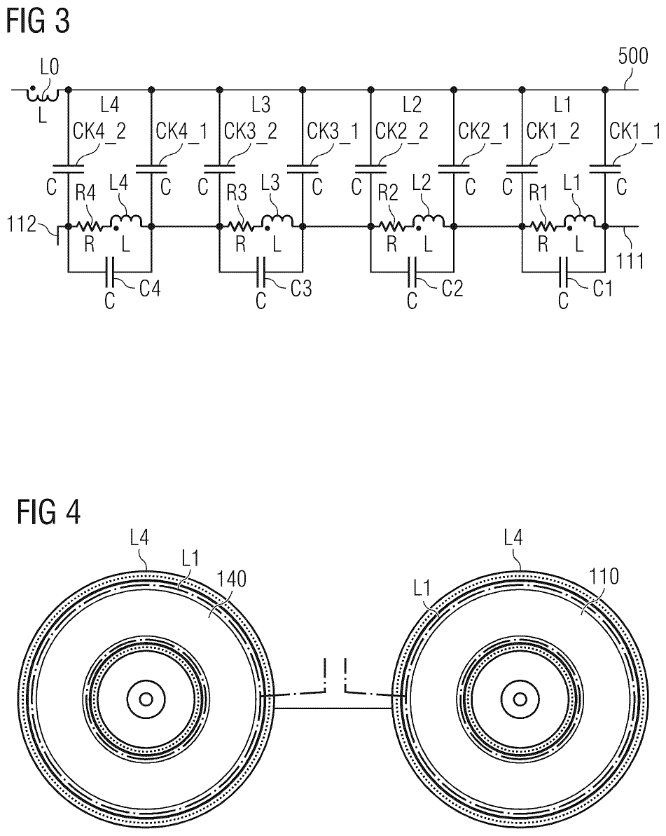

If, in addition to the magnetic and inductive couplings, the electrical and capacitive couplings are also to be compensated, it is important that the two coils 110; 120; 130; 140 also be manufactured and interconnected in such a way that the potential difference is always measured between the inputs of the windings of the two coils of the inner layers or the ends of the two coils. The measurement between the inputs is particularly advantageous in this case. Since in a multilayered coil only the first layer is wound directly onto the coil body 151; 152; 153; 154 and the subsequent layers are wound onto the respective preceding layers, the outer layers shield a part of the electrical field. The outer layers themselves are most exposed to the electrical field, such that-assuming an equal number of windings per layer—the outer layers have a greater coupling capacity with respect to the primary conductor; in this respect, see the circuit diagram of FIG. 3 with the layer L1 on the coil body and the layers L2, L3 and L4 arranged thereon.

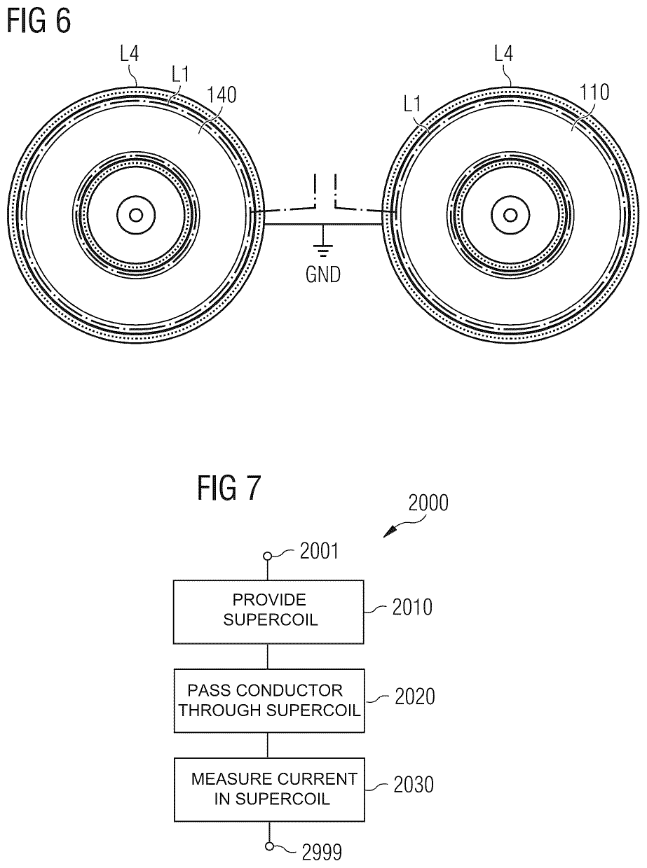

It is advantageous here that the at least two coils 110; 120; 130; 140 are electrically connected to one another in their outer winding layers L4 and the overall signal is determined between the inner winding layers L1. Furthermore, the connection of the outer winding layers L4 may be grounded. This is shown in FIGS. 5 and 6, wherein, in FIG. 5, the electrical equivalent circuit diagram of the two coils 110; 140 of FIG. 6 is illustrated with the grounding of the connection of the outer winding layers L4.

It is important here that the second coil, for example, is wound with the opposite winding sense but in the same winding direction as the first coil. The input is then swapped with the output in the second coil and both coils are mounted on top of one another. If the output of coil 1 is now connected to the new input of coil 2, as is illustrated in FIGS. 3 and 4, the signals of the measuring current add up, but the capacitive and inductive interference couplings of both coils will be subtracted. The compensation of the capacitive interference couplings in the output signal of the coil arrangement can be further improved by grounding the connecting line between the two coils, as is shown in FIGS. 5 and 6. The effect of reducing the capacitive interference coupling by combining coils by symmetrical coupling capacitances can be gathered from FIG. 5. The effect of reducing the capacitive interference coupling by combining coils by shielding the grounded layers can easily be gathered from FIG. 3. Both effects can also be combined.

The method according to the invention for producing a supercoil 200 for measuring a current in a conductor 500 comprises the following steps:
winding a first coil 110; 120; 130; 140;
winding a second coil 110; 120; 130; 140,
wherein the two coils 110; 120; 130; 140 have an identical coil body 151; 152; 153; 154 and are wound with the same type of wire, with the same number of winding layers, and the same number of windings, but wherein the two coils 110; 120; 130; 140 differ in the orientation of their windings; and
assembling the first coil 110; 120; 130; 140 and the second coil 110; 120; 130; 140 to form a supercoil 200, with the two coils 110; 120; 130; 140 electrically connected in series and spatially disposed on top of one another.

In this case, the first coil 110; 120; 130; 140 may be wound right-handed counter-clockwise and the second coil 110; 120; 130; 140 may be wound right-handed clockwise, wherein, upon assembly, inputs and outputs 111, 112; 121, 122; 131, 132; 141, 142 are swapped in the second coil 110; 120; 130; 140 or the second coil 110; 120; 130; 140 is tilted by 180°.

Likewise, the first coil 110; 120; 130; 140 may be wound right-handed counter-clockwise and the second coil 110; 120; 130; 140 may be wound left-handed clockwise, wherein, upon assembly, inputs and outputs are swapped in the second coil and the second coil is tilted by 180°.

Equally, the first coil 110; 120; 130; 140 may be wound right-handed clockwise and the second coil 110; 120; 130; 140 may be wound right-handed counter-clockwise, wherein, upon assembly, inputs and outputs 111, 112; 121, 122; 131, 132; 141, 142 are swapped in the second coil 110; 120; 130; 140 and the second coil is tilted by 180°.

Equally, the first coil 110; 120; 130; 140 may be wound right-handed clockwise and the second coil 110; 120; 130; 140 may be wound left-handed counter-clockwise, wherein, upon assembly, inputs and outputs 111, 112; 121, 122; 131, 132; 141, 142 are swapped in the second coil 110; 120; 130; 140 and the second coil is tilted by 180°.

Equally, the first coil 110; 120; 130; 140 may be wound left-handed clockwise and the second coil 110; 120; 130; 140 may be wound left-handed counter-clockwise, wherein, upon assembly, inputs and outputs 111, 112; 121, 122; 131, 132; 141, 142 are swapped in the second coil 110; 120; 130; 140 or the second coil is tilted by 180°.

Equally, the first coil 110; 120; 130; 140 may be wound left-handed clockwise and the second coil 110; 120; 130; 140 may be wound right-handed counter-clockwise, wherein, upon assembly, inputs and outputs 111, 112; 121, 122; 131, 132; 141, 142 are swapped in the second coil 110; 120; 130; 140 and the second coil is tilted by 180°.

Equally, the first coil 110; 120; 130; 140 may be wound left-handed counter-clockwise and the second coil 110; 120; 130; 140 may be wound left-handed clockwise, wherein, upon assembly, inputs and outputs 111, 112; 121, 122; 131, 132; 141, 142 are swapped in the second coil 110; 120; 130; 140 or the second coil is tilted by 180°.

Equally, the first coil 110; 120; 130; 140 may be wound left-handed counter-clockwise and the second coil 110; 120; 130; 140 may be wound right-handed clockwise, wherein, upon assembly, inputs and outputs 111, 112; 121, 122; 131, 132; 141, 142 are swapped in the second coil 110; 120; 130; 140 and the second coil is tilted by 180°.

FIG. 7 illustrates the method 2000 according to the invention for measuring a current in a conductor 500 between the start 2001 and the end 2999. The method 2000 comprises the following:
Step 2010: providing a supercoil 200 as described above;
Step 2020: passing a conductor 500 through the supercoil 200; and
Step 2030: measuring the current in the supercoil 200.

It should generally be noted that twisting the connection of both coils 110, 120, 130, 140 by 180° reduces interference caused by magnetic fields perpendicular to the axis of the conductor.

1. An apparatus for measuring a current in a conductor, the apparatus comprising:
at least two coils, being a first coil and a second coil;
said at least two coils having an identical coil body, and having been wound with a same type of wire, with a same number of winding layers, and a same number of windings;
said at least two coils being electrically connected in series and being arranged spatially on top of one another, and said at least two coils differing in an orientation of the windings thereof, with said at least two coils forming a supercoil; and
said supercoil being formed to pass the conductor therethrough for measuring the current in the conductor.

2. The apparatus according to claim 1, wherein said at least two coils have inputs and outputs and said inputs and outputs are twisted by 180° relative to one another.

3. The apparatus according to claim 1, wherein said at least two coils are electrically connected to one another in outer winding layers thereof and an overall signal is determined between the inner winding layers.

4. The apparatus according to claim 3, wherein a connection of said outer winding layers is grounded.

5. A method of producing a supercoil for measuring a current in a conductor, the method comprising the following steps:
winding a first coil;
winding a second coil;
the first and second coils having an identical coil body and being wound with a same type of wire with a same number of winding layers and a same number of windings, and winding the first and second coils with windings that differ in an orientation thereof;
assembling the first coil and the second coil to form a supercoil, with the first and second coils being electrically connected in series and arranged spatially on top of one another.

6. The method according to claim 5, which comprises:
winding the first coil right-handed counter-clockwise;
winding the second coil right-handed clockwise; and
upon assembling the first and second coils, swapping inputs and outputs in the second coil or tilting the second coil by 180°.

7. The method according to claim 5, which comprises:
winding the first coil right-handed counter-clockwise;
winding the second coil left-handed clockwise; and
upon assembling the first and second coils, swapping inputs and outputs in the second coil and tilting the second coil by 180°.

8. The method according to claim 5, which comprises:
winding the first coil right-handed clockwise;
winding the second coil right-handed counter-clockwise; and
upon assembling the first and second coils, swapping inputs and outputs in the second coil or tilting the second coil by 180°.

9. The method according to claim 5, which comprises:
winding the first coil right-handed clockwise;
winding the second coil left-handed counter-clockwise; and
upon assembling the first and second coils, swapping inputs and outputs in the second coil and tilting the second coil by 180°.

10. The method according to claim 5, which comprises:
winding the first coil left-handed clockwise;
winding the second coil left-handed counter-clockwise; and
upon assembling the first and second coils, swapping inputs and outputs in the second coil or tilting the second coil by 180°.

11. The method according to claim 5, which comprises:
winding the first coil left-handed clockwise;
winding the second coil right-handed counter-clockwise; and
upon assembling the first and second coils, swapping inputs and outputs in the second coil and tilting the second coil by 180°.

12. The method according to claim 5, which comprises:
winding the first coil left-handed counter-clockwise;
winding the second coil left-handed clockwise; and
upon assembling the first and second coils, swapping inputs and outputs in the second coil or tilting the second coil by 180°.

13. The method according to claim 5, which comprises:
winding the first coil left-handed counter-clockwise;
winding the second coil right-handed clockwise; and
upon assembling the first and second coils, swapping inputs and outputs in the second coil and tilting the second coil by 180°.

14. A method for measuring a current in a conductor, the method comprising the following steps:
providing the apparatus according to claim 1 forming the supercoil;
guiding the conductor through the supercoil; and
measuring the current in the supercoil.
